(19) United States
(12) Patent Application Publication
(10) Pub. No.: US 2019/0288242 A1
(43) Pub. Date: Sep. 19, 2019

(54) METHOD FOR PREPARING ORGANIC LIGHT EMITTING DIODE BY USING THERMAL TRANSFER FILM

(71) Applicant: CHIEN HWA COATING TECHNOLOGY, INC., HSINCHU CITY (TW)

(72) Inventor: HUNG-HSIN SHIH, TAIPEI CITY (TW)

(21) Appl. No.: 15/982,142

(22) Filed: May 17, 2018

(30) Foreign Application Priority Data
Mar. 19, 2018 (TW) 107109325

(51) Int. Cl. H01L 51/56; H01L 51/52; H01L 51/00

(52) U.S. Cl. CPC H01L 51/56; H01L 51/0013; H01L 51/529

(57) ABSTRACT

A method for preparing organic light emitting diode (OLED) by using thermal transfer film is revealed. A first transfer layer on a thermal transfer film is transferred onto a substrate by thermal transfer printing for overcoming shortcomings of the conventional vacuum evaporation including complicated processes and low material efficiency. Only less than 50% material reaches the substrate after the vacuum evaporation.

### BACKGROUND OF THE INVENTION

### Field of the Invention

The present invention relates to a method for preparing Organic Light Emitting Diode (OLED), especially to a method for preparing Organic Light Emitting Diode (OLED) by using a thermal transfer film.

### Description of Related Art

A semiconductor is a kind of material whose electrical conductivity value falls between that of an insulator and a conductor. The semiconductor has a profound impact on either technology or economic development. The most common semiconductor materials include silicon, germanium, gallium arsenide, etc. The silicon is the most common and is used in the widespread commercial applications.

Virtually all aspects of our lives are touched by semiconductor products. For example, Light-Emitting Diode (LED) and Laser Diode (LD) have been applied to illumination, indicator light sources, optical information storage system, laser printer, optical fiber communication and medical field, etc. Other products such as light detectors, solar cells, optical amplifier, transistor, etc. have an enormous impact on our lives in this high tech age. The display quality is particularly important in the era of video communication.

The display has become an essential means in human-computer interaction along with the advanced technology and the prevalence of personal computer, internet use and information & communication technology. The rapidly developing display technology is further booming the flat-panel display industry.

A conventional Cathode Ray Tube (CRT) screen is bulky and heavy for users. Thus the CRT screen has been gradually replaced by a thinner and larger sized Plasma Display Panel (PDP) and much thinner and lighter Liquid Crystal Display (LCD).

OLED (Organic Light Emitting Diodes), also called organic electroluminescence (OEL), is an offshoot of the next generation of flat panel display technology. Besides compactness, OLED displays have unique advantages including flexibility, portability, full color capability and high brightness, low power consumption, wide viewing angle, no image sticking, etc. Thus the OLED has become a mainstream in the flat panel display industry. Experts in universities and their industrial partners are dedicated to research and development of this new technology.

Under the influence of a voltage applied to OLED, holes and electrons are injected into the hole injection layer and the electron injection layer, and passed through the hole transport layer and the electron transport layer respectively. Then the holes and electrons enter the light emitting layer and recombine to form excitons that relax to the ground sate by release of energy. The energy is released as light due to relaxation of excitons in the singlet or triplet state to the ground state. Owing to the light emitting material used and spin state characteristics of the electrons, only 25% of the energy released (from singlet to the ground state) is used as OLED luminescence while the rest 75% (from triplet to the ground state) is released in the form of phosphorescence or heat. The frequency of the radiation depends on the band gap of the material used so that the color of the light produced can be varied.

The principles of OLED are similar to those of LED (light emitting diode). The difference between OLED and LED is that OLED uses organic compounds as materials that emit light and the light emission of OLED is more efficient with most of the photons generated across the visible light spectrum.

Moreover as OELD is self-emitting, no backlight is required. Thus the OLED has optimum visibility and high brightness. The OLED features on low driving-voltage, high efficiency, fast response, light weight, slim profile, etc. Compared with LCD, OLED has no image retention and having a wide temperature range. OLED's response time at low temperature is the same as that at room temperature while the temperature affects LCD. A longer response time is required at low temperature and liquid crystals can even freeze and cause performance problems.

However, certain problems occur during production processes of semiconductor products (such as OLED). Under high vacuum, raw materials are heated and evaporated into atoms or molecules by current, electron beam irradiation, and laser and then to be deposited on a substrate required evenly. A metal mask is required during vacuum evaporation. The method is difficult to scale because that highly accurate positioning of the metal mask is required and larger metal masks are easy to lose accuracy. Thus the substrate used is limited to small scale one, difficult to scale up and unable to be mass produced. The cost of the metal mask is extremely high and a cleaning process is required during production of the metal mask. The positioning of the metal mask should be very accurate.

Furthermore, a lot of LOED materials are wasted during the vacuum evaporation. The vacuum evaporation is simple but inefficient because only 10-40% material reaches the substrate after the process. The OLED has low material utilization.

Thus there is room for improvement and there is a need to provide a novel OLED for solving problems that occurs during conventional vacuum evaporation (such as difficulty in mass production of large-scale products and low material efficiency).

### SUMMARY OF THE INVENTION

Therefore it is a primary object of the present invention to provide a method for preparing Organic Light Emitting Diode (OLED) by using a thermal transfer film. At least two transfer layers on the thermal transfer film are heated and transferred onto a substrate by thermal transfer printing for solving problems of complicated processes and low material efficiency of the conventional vacuum evaporation. Only less than 50% material reaches the substrate after the vacuum evaporation.

In order to achieve the above object, a method for preparing OLED by using a thermal transfer film according to the present invention includes the step of: taking a thermal transfer film that includes a heat resistant layer, a base layer, a functional layer and a first transfer layer from top to bottom in turn; taking a substrate and setting the substrate under the thermal transfer film; and heating the thermal transfer film for transferring the first transfer layer onto the substrate and removing the heat resistant layer, the base layer, and the functional layer.

The heat resistant layer is composed of zinc stearate (SPZ-100F), zinc stearyl phosphate (LBT-1830) and cellulose acetate propionate (CAP-504-0.2).

The thickness of the heat resistant layer ranges from 0.1 um to 3 um.

The base layer is made from a material selected from the group consisting of polyethylene terephthalate (PET), polyimide (PI), poly(ethylene naphthalate) (PEN) and a combination thereof.

The thickness of the base layer ranges from 2 um to 100 um.

The functional layer is made from a material selected from the group consisting of silver, aluminum, magnesium, and a combination thereof.

The functional layer is made from a material selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyvinyl chloride (PVC) resin and a combination thereof.

The thickness of the functional layer ranges from 0.3 um to 10 um.

The first transfer layer further includes a second transfer layer that is located over the first transfer layer.

Both the first transfer layer and the second transfer layer are made from materials selected from a hole injection material, a hole transport material, a RGB light emitting material, an electron transport material, an electron injection material, a metallic nanomaterial, a carbon nanotube conductive material and a combination thereof respectively.

The first transfer layer and the second transfer layer are made from materials selected from the group consisting of an arylamine, a polymer mixture of ionomers, a P-dopant, a phenyl arylamine, an organic fluorescent material, an organic phosphorescent material, a thermally-activated delayed fluorescence (TADF) material, a heavy metal complex, an organic polycyclic aromatics, a polycyclic aromatic hydrocarbon (PAH), a blue emitting material, a green emitting material, a red emitting material, a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative, a N-dopant, a metal, an alloy, a metal complex, a metal compound, a metal oxide, an electroluminescent material, an electroactive material, and a combination thereof respectively.

The thickness of both the first transfer layer and the second transfer layer is 20-200 nm.

The disposition process for arranging the first transfer layer and the second transfer layer includes vacuum evaporation, spin coating, slot die coating, inkjet printing, gravure printing, screen printing, chemical vapor deposition (CVD), physical vapor deposition (PVD), and sputtering.

The substrate is made from a material selected from the group consisting of glass, polyimide (PI), polyethylene terephthalate (PET) and a combination thereof.

The step of taking a substrate and setting the substrate under the thermal transfer film further includes a step of arranging a material layer at the substrate and the material layer is selected from a group consisting of indium tin oxide (ITO), polymer, conductive polymer, small molecule organic light emitting diode (OLED), polymer light emitting diode (PLED), and a combination thereof.

In the step of heating the thermal transfer film for transferring the first transfer layer onto the substrate and removing the heat resistant layer, the base layer, and the functional layer, a thermal print head (TPH) is used to heat the thermal transfer film.

In the step of heating the thermal transfer film for transferring the first transfer layer onto the substrate and removing the heat resistant layer, the base layer, and the functional layer, the thermal transfer film is heated up to 80-300 degrees Celsius (° C.).

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a flow chart showing steps of an embodiment according to the present invention;

FIG. 2A-2C are schematic drawings showing structure of respective step of an embodiment according to the present invention;

FIG. 3A is a schematic drawing showing test results of an embodiment using green emitting material according to the present invention;

FIG. 3B is a schematic drawing showing test results of another embodiment using green emitting material according to the present invention; and

FIG. 3C is a schematic drawing showing test results of a further embodiment using green emitting material according to the present invention.

### DETAILED DESCRIPTION OF THE PREFERRED EMBODIMENT

In order to learn features and functions of the present invention, please refer to the following embodiments and the related descriptions.

In order to solve problems of the conventional vacuum evaporation used for preparing organic light emitting diode (OLED) (such as difficult scale-up and low material efficiency) that cause high production cost, a method for preparing OLED by using a thermal transfer film according to the present invention is provided.

The features, the structure of the method for preparing OLED by using a thermal transfer film according to the present invention are revealed by the following embodiments.

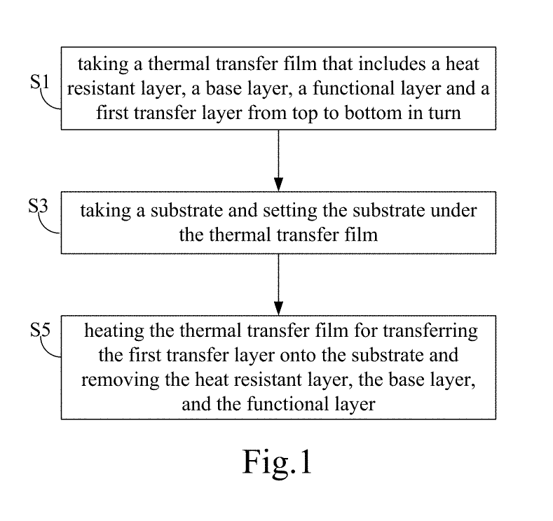

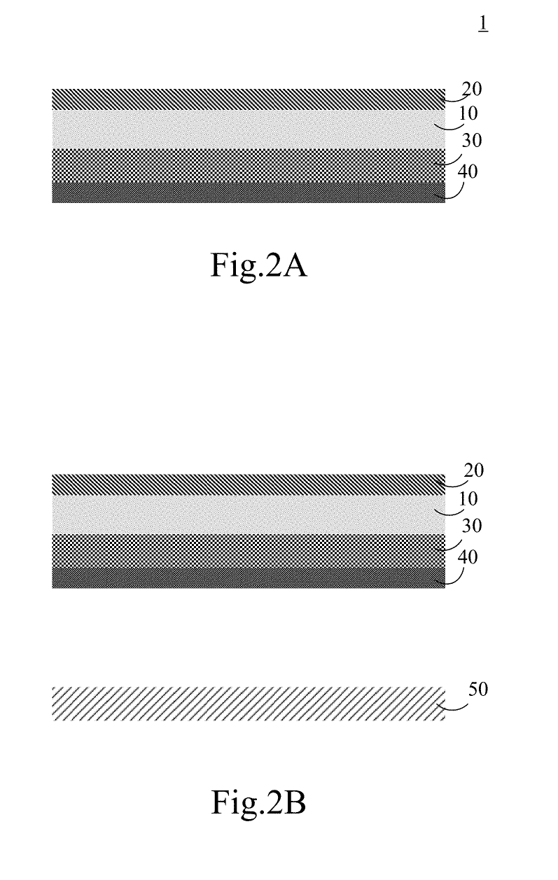

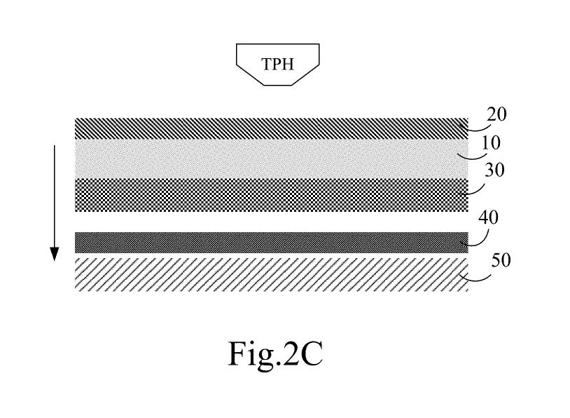

Refer to FIG. 1 and FIG. 2A-2C, a method for preparing OLED by using a thermal transfer film according to the present invention includes the following steps.

S1: taking a thermal transfer film that includes a heat resistant layer, a base layer, a functional layer and a first transfer layer from top to bottom in turn;

S3: taking a substrate and setting the substrate under the thermal transfer film; and

S5: heating the thermal transfer film for transferring the first transfer layer onto the substrate and removing the heat resistant layer, the base layer, and the functional layer.

Refer to FIG. 2A, take a thermal transfer film 1 that includes a heat resistant layer 20, a base layer 10, a functional layer 30 and a first transfer layer 40 from top to bottom in turn, as shown in the step S1.

The heat resistant layer 20 is composed of zinc stearate (SPZ-100F), zinc stearyl phosphate (LBT-1830) and cellulose acetate propionate (CAP-504-0.2). The thickness of the heat resistant layer 20 is ranging from 0.1 um to 3 um.

In order to produce the heat resistant layer 20, use the rotogravure printing machine (Hsing Wei Machine Industry Co., Ltd.) with different mesh count 135, 150 or 250 to print a heat resistant layer solution on the base layer 10. Then the heat resistant layer 20 is formed after the base layer 10 being heated in an oven at 50˜120° C. for 1˜10 min.

For preparing the heat resistant layer solution, take 60.2 g butanone (MEK), 25.8 g toluene, 1.6 g zinc stearate (SPZ-100F), 1 g zinc stearyl phosphate (LBT-1830), 0.5 g nano modified clay (C34-M30), 0.2 g paint additive (KP-341), 0.2 g anionic surfactant (KC-918), 10 g cellulose acetate propionate (CAP-504-0.2) and 0.25 g dispersant (BYK103) to mix and get a first solution. Then stir the first solution for 2 hours for dissolving all of the solutes completely.

Then take 3 g fatty alcohol polyoxyethylene ether (L75) and 3 g butanone (MEK) to form a second solution. Lastly mix the first solution and the second solution to get the heat resistant layer solution.

The base layer 10 is made from a material selected from the group consisting of polyethylene terephthalate (PET), polyimide (PI), poly(ethylene naphthalate) (PEN) and a combination thereof. The thickness of the base layer 10 is ranging from 2 um to 100 um.

The functional layer 30 is made from a material selected from the group consisting of silver, aluminum, magnesium, and a combination thereof.

The material for the functional layer 30 can also be selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyvinyl chloride (PVC) resin and a combination thereof.

The thickness of the functional layer 30 is ranging from 0.3 um to 10 um. For preparing the functional layer 30, use the electric gravure coating machine (K Printing Proofer of RK printcoat instruments) with different mesh count such as 135 or 250 to print a functional layer solution on the base layer 10. Then the base layer 10 is heated in an oven at 30˜140° C. for 1˜30 min and later cured by UV radiation so as to form the functional resistant layer 30.

In order to prepared the functional layer solution, first dissolve 14.85 g trimethylolpropane triacrylate (TMPTA), 0.93 g polyvinyl butyral, 2.78 g waterborne resin (Joncry 671) in 10 g 1-methoxy-2-propanol and 10 g butanone (MEK) to form a third solution. Dissolve 1.25 g UV curing agent (Irgacure 369) in 5 g butanone (MEK) to form a fourth solution. Dissolve 0.19 g photoinitiator (Irgacure 184) in 2.5 g butanone (MEK) to form a fifth solution.

Then mix 5 g the third solution, 0.81 g the fourth solution and 0.352 g the fifth solution to form a formulated solution. Lastly use butanone (MEK) as solvent to dilute the formulated solution to the dissolved solid content required.

The first transfer layer 40 further includes a second transfer layer that located thereover. The number of the transfer layer included in the first transfer layer 40 is not limited. It can be a single layer, two layers or multiple layers. The thickness of the first transfer layer 40 and that of the second transfer layer are ranging from 20 nm to 200 nm.

The transfer layer 40 and the second transfer layer are made from materials selected from the group consisting of a hole injection material, a hole transport material, a RGB light emitting material, an electron transport material, an electron injection material, a metallic nanomaterial, a carbon nanotube conductive material and a combination thereof respectively.

The transfer layer 40 and the second transfer layer can be an anode, a hole injection layer, a hole transport layer, a light emitting layer, an electron transport layer, an electron injection layer, a cathode, or a combination thereof.

The anode and the cathode are generally made from conductive materials such as a metal, an alloy, a metal compound, a metal oxide, an electroactive material, a conductive dispersion and a conductive polymer. For example, the materials include gold, platinum, palladium, aluminum, calcium, titanium, titanium nitride (TiN), indium tin oxide (ITO), fluorine-doped tin oxide (FTO), polyaniline, etc.

The hole injection layer is mad from a material selected from the group consisting of an arylamine, a polymer mixture of ionomers (such as PEDOT:PSS), a P-dopant and a combination thereof.

The hole transport layer is made from a material selected from the group consisting of an arylamine, a phenyl arylamine and a combination thereof.

The light emitting layer is made from a material selected from the group consisting of an organic fluorescent material, an organic phosphorescent material, a thermally-activated delayed fluorescence (TADF) material, a heavy metal complex (such as iridium, platinum, silver, osmium, lead, etc.), an organic polycyclic aromatic, a polycyclic aromatic hydrocarbon (PAH), a blue emitting material, a green emitting material, a red emitting material, an electroluminescent material and a combination thereof.

The electron transport layer is made from a material selected from the group consisting of a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative and a combination thereof.

The electron injection layer is made from a material selected from the group consisting of an N-dopant, a metal complex and a metal compound (such as an alkali metal compound, an alkaline earth metal compound, etc.), and a combination thereof.

The first transfer layer 40 and the second transfer layer are disposed by vacuum evaporation, spin coating, slot die coating, inkjet printing, gravure printing, screen printing, chemical vapor deposition (CVD), physical vapor deposition (PVD), and sputtering.

Next, as shown in the step S3 (FIG. 2B), take a substrate 50 and set the substrate 50 under the thermal transfer film 1.

The substrate 50 is made from a material selected from the group consisting of glass, polyimide (PI), polyethylene terephthalate (PET) and a combination thereof.

The step S3 further includes the following steps.

S31: arranging a material layer on the substrate and the material layer is selected from the group consisting of indium tin oxide (ITO), polymer, conductive polymer, small molecule organic light emitting diode (OLED), polymer light emitting diode (PLED), and a combination thereof.

Then as shown in the step S5 (FIG. 2C), heat the thermal transfer film 1 for transferring the first transfer layer 40 onto the substrate 50 and remove the heat resistant layer 20, the base layer 10, and the functional layer 30. In the step S5, a thermal print head (TPH) is used to heat the thermal transfer film 1 up to 80-300 degrees Celsius (° C.). The heat resistant layer 20, the base layer 10, and the functional layer 30 are removed after thermal transfer printing.

Lastly keep using the thermal transfer film 1 to perform thermal transfer printing until the anode, the hole injection layer, the hole transport layer, the light emitting layer, the electron transport layer, the electron injection layer, and the cathode being stacked on the substrate 50 in turn. Thus an organic light emitting diode is formed.

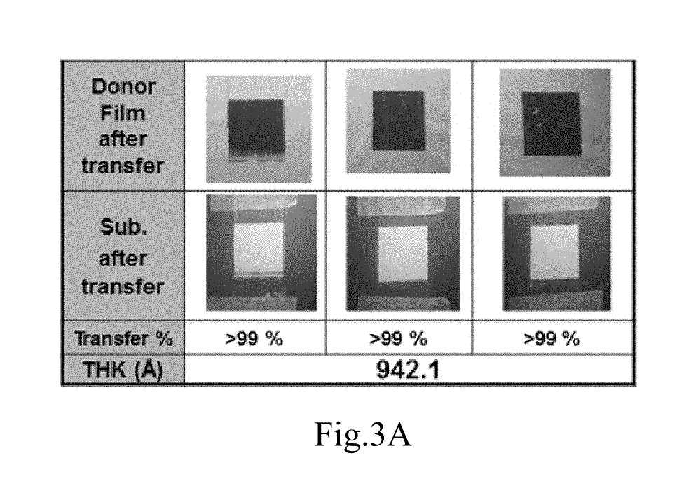

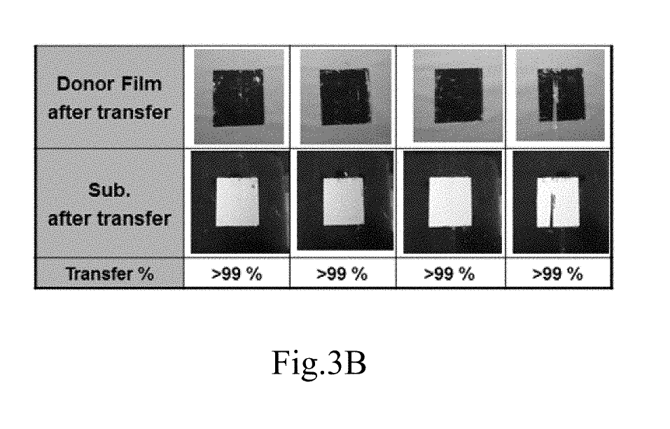

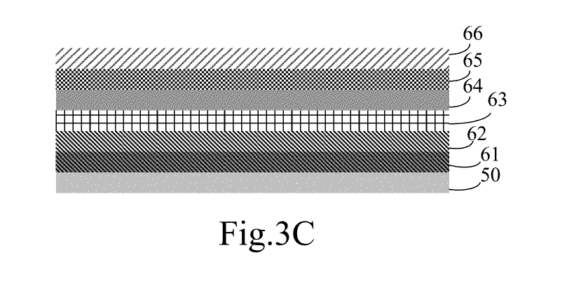

Refer to FIG. 3A, an embodiment using green emitting material is revealed. In the first transfer layer 40 of the thermal transfer film 1 (the donor film), 1,3,5-Tris(1-phenyl-1H-benzimidazol-2-yl)benzene (TPBI) is used as the electron transfer layer and is disposed on the functional layer 30. CBP:Ir(ppy)₃(4,4′-Bis(carbazol-9-yl)biphenyl:Tris(2-phenylpyridine) iridium(III)) is used as the light emitting layer in the second transfer layer and is arranged at the first transfer layer 40. The first transfer layer 40 and the second transfer layer are heated and transferred onto the glass substrate 50 (Sub). The substrate 50 has already been provided with indium tin oxide (ITO) as the anode and PEDOT:PSS(Poly(3,4-ethylenedioxythiophene)-poly(styrenesulfonate)) in advance. The thermal print head (TPH) is used for thermal transfer printing and the results are shown in FIG. 3A. The thickness (THK) is 942.1 Å and the transfer ratio is higher than 99% after repeating the experiments.

Refer to FIG. 3B, another embodiment using green emitting material is disclosed. 1,3,5-Tris(1-phenyl-1H-benzimidazol-2-yl)benzene (TPBI) is used as the electron transfer layer in the first transfer layer 40 of the thermal transfer film 1 (the donor film) and is disposed on the functional layer 30. CBP:Ir(ppy)₃(4,4′-Bis(carbazol-9-yl)biphenyl:Tris(2-phenylpyridine) iridium(III)) is used as the light emitting layer in the second transfer layer and is arranged at the first transfer layer 40. The first transfer layer 40 and the second transfer layer are heated and transferred onto the glass substrate 50 (Sub). The substrate 50 has already been provided with indium tin oxide (ITO) and 4,4′,4″-Tris(carbazol-9-yl)-triphenylamine (TCTA) by vacuum evaporation in advance. After the thermal transfer printing using thermal print head (TPH), lithium fluoride (LiF) and aluminum (Al) are disposed on TPBI by vapor deposition and used as the electron injection layer and the cathode respectively to form the organic light emitting diode (OLED). Refer to FIG. 3C, the structure of the OLED includes indium tin oxide (ITO) 61, 4,4′,4″-Tris(carbazol-9-yl)-triphenylamine 62, CBP:Ir(ppy)₃ 63, 1,3,5-Tris(1-phenyl-1H-benzimidazol-2-yl)benzene 64, lithium fluoride (LiF) 65 and aluminum 66 over the substrate 50 in turn. As shown in FIG. 3B, the transfer ratio is higher than 99% after repeating the experiments. As shown in the FIG. 3A and FIG. 3B, not only the electron transfer layer of the light emitting layer of the OLED can be formed by thermal transfer printing, the respective layer of the OLED including the anode, the hole injection layer, the hole transport layer, the electron injection layer, the cathode, etc. can also be transferred onto the substrate 50 by using the thermal print head (TPH) for thermal transfer printing.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A method for preparing organic light emitting diode (OLED) by using a thermal transfer film comprising the steps of:
taking a thermal transfer film that includes a heat resistant layer, a base layer, a functional layer and a first transfer layer from top to bottom in turn;
taking a substrate and setting the substrate under the thermal transfer film; and
heating the thermal transfer film for transferring the first transfer layer onto the substrate and removing the heat resistant layer, the base layer, and the functional layer.

2. The method as claimed in claim 1, wherein the heat resistant layer includes zinc stearate, zinc stearyl phosphate and cellulose acetate propionate.

3. The method as claimed in claim 1, wherein a thickness of the heat resistant layer is ranging from 0.1 um to 3 um.

4. The method as claimed in claim 1, wherein the base layer is made from a material selected from the group consisting of polyethylene terephthalate (PET), polyimide (PI), poly(ethylene naphthalate) (PEN) and a combination thereof.

5. The method as claimed in claim 1, wherein a thickness of the base layer is ranging from 2 um to 100 um.

6. The method as claimed in claim 1, wherein the functional layer is made from a material selected from the group consisting of silver, aluminum, magnesium, and a combination thereof.

7. The method as claimed in claim 1, wherein the functional layer is made from a material selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyvinyl chloride (PVC) resin and a combination thereof.

8. The method as claimed in claim 1, wherein a thickness of the functional layer ranges from 0.3 um to 10 um.

9. The method as claimed in claim 1, wherein the first transfer layer further includes a second transfer layer and the second transfer layer is located over the first transfer layer.

10. The method as claimed in claim 9, wherein the first transfer layer and the second transfer layer are made from materials selected from the group consisting of a hole injection material, a hole transport material, a RGB light emitting material, an electron transport material, an electron injection material, a metallic nanomaterial, a carbon nanotube conductive material and a combination thereof respectively.

11. The method as claimed in claim 9, wherein the first transfer layer and the second transfer layer are made from materials selected from the group consisting of an arylamine, a polymer mixture of ionomers, a P-dopant, a phenyl arylamine, an organic fluorescent material, an organic phosphorescent material, a thermally-activated delayed fluorescence (TADF) material, a heavy metal complex, an organic polycyclic aromatics, a polycyclic aromatic hydrocarbon (PAH), a blue emitting material, a green emitting material, a red emitting material, a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative, a N-dopant, a metal, an alloy, a metal complex, a metal compound, a metal oxide, an electroluminescent material, an electroactive material, and a combination thereof respectively.

12. The method as claimed in claim 9, wherein a thickness of the first transfer layer is ranging from 20-200 nm and a thickness of the second transfer layer is ranging from 20-200 nm.

13. The method as claimed in claim 9, wherein a disposition process for arranging the first transfer layer and the second transfer layer is selected from the group consisting of vacuum evaporation, spin coating, slot die coating, inkjet printing, gravure printing, screen printing, chemical vapor deposition (CVD), physical vapor deposition (PVD), and sputtering.

14. The method as claimed in claim 1, wherein the substrate is made from a material selected from the group consisting of glass, polyimide (PI), polyethylene terephthalate (PET) and a combination thereof.

15. The method as claimed in claim 1, wherein the step of taking a substrate and setting the substrate under the thermal transfer film further includes a step of:
arranging a material layer at the substrate and the material layer is selected from a group consisting of indium tin oxide (ITO), polymer, conductive polymer, small molecule organic light emitting diode (OLED), polymer light emitting diode (PLED), and a combination thereof.

16. The method as claimed in claim 1, wherein in the step of heating the thermal transfer film for transferring the first transfer layer onto the substrate and removing the heat resistant layer, the base layer, and the functional layer, a thermal print head (TPH) is used to heat the thermal transfer film.

17. The method as claimed in claim 1, wherein in the step of heating the thermal transfer film for transferring the first transfer layer onto the substrate and removing the heat resistant layer, the base layer, and the functional layer, the thermal transfer film is heated up to 80-300 degrees Celsius (° C.).
